(19) United States
(12) Patent Application Publication
(10) Pub. No.: US 2024/0180038 A1
(43) Pub. Date: May 30, 2024

(54) APPARATUS AND METHOD FOR REGENERATING A LEAD-ZIRCONATE-TITANATE THIN FILM

(71) Applicant: Robert Bosch GmbH, Stuttgart (DE)

(72) Inventors: Kuan-Ting Ho, Reutlingen (DE); Daniel Monteiro Diniz Reis, Esslingen Am Neckar (DE); Mathias Mews, Reutlingen (DE)

(21) Appl. No.: 18/510,012

(22) Filed: Nov. 15, 2023

(30) Foreign Application Priority Data
Nov. 25, 2022 (DE) 10 2022 212 623.8

(51) Int. Cl. H10N 30/04; H10N 30/853

(52) U.S. Cl. CPC H10N 30/04; H10N 30/8554

(57) ABSTRACT

A method and apparatus for regenerating a lead-zirconate-titanate thin film. The apparatus includes a heater configured to treat the lead-zirconate-titanate thin film at a specified temperature below 350º Celsius by means of a heater different from the lead-zirconate-titanate thin film, wherein the apparatus includes a device for generating an electrical field, wherein the device is configured to generate an electrical field having a specified electrical field strength, and to treat the lead-zirconate-titanate thin film by means of the electrical field.

### CROSS REFERENCE

The present application claims the benefit under 35 U.S.C. § 119 of German Patent Application No. DE 10 2022 212 623.8 filed on Nov. 25, 2022, which is expressly incorporated herein by reference in its entirety.

### FIELD

The present invention relates to an apparatus and method for regenerating a lead-zirconate-titanate thin film.

### BACKGROUND INFORMATION

J. Wang, C. Salm, E. Houma, M. Nguyen, and J. Schmitz, “Humidity and polarity influence on MIM PZT capacitor degradation and breakdown”, in 2016 IEEE International Integrated Reliability Workshop (IIRW) , 2016, pp. 65-68, describes that an extended life of a PZT thin film is achievable by heat as well as by an electrical field.

### SUMMARY

By the apparatus and the method according to the present invention, a regeneration treatment for increasing or restoring an original resistance of a lead-zirconate-titanate thin film may be achieved after a reduction in resistance through the use thereof at low temperatures. The higher resistance causes less leakage current. Thus, the regeneration treatment is desirable.

According to an example embodiment of the present invention, The method for regenerating a lead-zirconate-titanate thin film provides that the lead-zirconate-titanate thin film is treated at a temperature under 350° Celsius at least partially produced by a heater different from the lead-zirconate-titanate thin film, and with the simultaneous effect on the lead-zirconate thin film of an electrical field of a specified electrical field strength.

Preferably, the specified temperature is 220° Celsius or below 220° Celsius.

In one example embodiment of the present invention, the lead-zirconate-titanate thin film is heated by means of the heater from outside the lead-zirconate-titanate thin film. This allows heat transfer from outside the thin film.

In one example embodiment of the present invention, the lead-zirconate-titanate thin film is heated by means of the heater in the lead-zirconate-titanate thin film. This improves heat transfer.

Preferably, according to an example embodiment of the present invention, a resistance of the lead-zirconate-titanate thin film is determined, wherein an end of regeneration is detected when the resistance reaches or exceeds a specified resistance value. The thin film is thereby produced having at least the desired resistance.

According to an example embodiment of the present invention, the apparatus comprises a heater different from the lead-zirconate-titanate thin film, which is configured to treat the lead-zirconate-titanate thin film at a predetermined temperature below 350° Celsius, wherein the apparatus comprises a device for generating an electrical field, wherein the device is configured to generate an electrical field having a specified electrical field strength, and to treat the lead-zirconate-titanate thin film by means of the electrical field.

Preferably, according to an example embodiment of the present invention, the apparatus comprises a controller configured to control the heater and the device for generating the electrical field to simultaneously treat the lead-zirconate-titanate thin film for a specified treatment time.

According to an example embodiment of the present invention, the apparatus is preferably configured such that the specified temperature is below 220°, preferably below 200° Celsius. Regeneration with less heat is thus possible. By applying the electrical field simultaneously, it is ensured that a duration of regeneration is less than one hour.

In one example embodiment of the present invention, the apparatus is configured to heat the lead-zirconate-titanate thin film by means of a heater near the lead-zirconate-titanate thin film. This allows the thin film to be heated from the outside.

In one example embodiment of the present invention, the apparatus is configured to heat the lead-zirconate-titanate thin film by means of a heater in the lead-zirconate-titanate thin film. This allows the thin film to be efficiently heated from the inside.

It may be provided that the apparatus is configured to determine a resistance of the lead-zirconate-titanate thin film and to detect an end of regeneration when the resistance reaches or exceeds a specified resistance value. Thus, a desired minimum resistance value is adjustable.

Further advantageous embodiments of the present invention can be taken from the following description and the figures.

### BRIEF DESCRIPTION OF THE DRAWINGS

FIG. 1 shows a schematic illustration of a regeneration apparatus, according to an example embodiment of the present invention.

FIG. 2 shows a method of regeneration, according to an example embodiment of the present invention.

### DETAILED DESCRIPTION OF EXAMPLE EMBODIMENTS

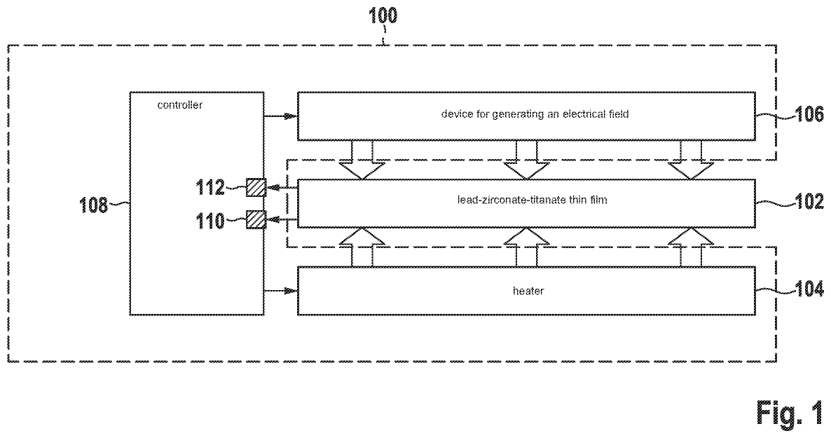

In FIG. 1, an apparatus 100 for regenerating a lead-zirconate-titanate thin film 102 is shown schematically.

The apparatus 100 comprises a heater 104, a device 106 for generating an electrical field, and a controller 108. The controller 108 may also be disposed outside of the apparatus 100.

The heater 104 is a device different from the lead-zirconate-titanate thin film. The heater 104 is configured to treat the lead-zirconate-titanate thin film 102 at a temperature produced at least in part by the heater 104.

In one embodiment, the heater 104 is disposed near the lead-zirconate-titanate thin film 102, i.e., outside the lead-zirconate-titanate thin film 102.

In one embodiment, the heater 104 is disposed in the lead-zirconate-titanate thin film 102.

The device 106 is configured to generate an electrical field having a specified electrical field strength and to treat the lead-zirconate-titanate thin film 102 by means of the electrical field. In the example, the device 106 is disposed outside of the lead-zirconate-titanate thin film 102.

The controller 108 is configured to actuate said device in a method for regeneration.

The controller 108 is configured, for example, to control the heater 104 and the device 106 to simultaneously treat the lead-zirconate-titanate thin film 102 for a specified treatment time.

In one embodiment, the apparatus 100 is configured to determine a resistance of the lead-zirconate-titanate thin film 102 and to detect an end of regeneration when the resistance reaches or exceeds a specified resistance value.

For example, the apparatus 100 comprises an ascertaining device 110 configured to ascertain the resistance.

For example, the apparatus 100 comprises a measuring device 112 configured to ascertain a temperature of the lead-zirconate-titanate thin film 102. The measuring device 112 and the ascertaining device 110 communicate the respective measured values to the controller 108.

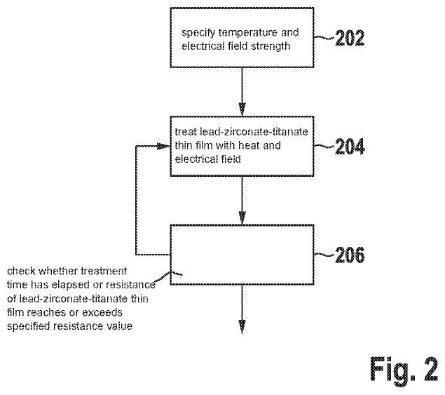

FIG. 2 shows steps of the method.

The method for regenerating the lead-zirconate-titanate thin film 102 comprises a step 202.

In step 202, a temperature and an electrical field strength are specified.

It may be provided that a treatment time is specified. Examples include:

| Temperature of | Electrical field | Treatment |
|---|---|---|
| heat treatment [° C.] | strength [kV/cm] | time [sec] |
| 350 | 0 | 3600 |
| 350 | −160 | 2 |
| 275 | −20 | 3600 |
| 275 | −200 | 125 |
| 240 | −200 | 780 |
| 220 | −160 | 3600 |
| 220 | −200 | 2500 |

The specified temperature is preferably specified below 350°. Regeneration at a lower temperature than 350° C. and the associated electrical field strengths are thus possible. Other combinations of electrical field strength and temperature in the range from −200 kV/cm to 0 kV/cm as shown in the table, and 350° Celsius to 220° Celsius respectively, are also possible. It is particularly advantageous if the temperature is specified as 220° C. or below 220° Celsius. The advantage of this is the temperature lower than 350° Celsius.

Subsequently, a step 204 is performed.

In step 204, the lead-zirconate-titanate thin film 102 is treated with heat of the temperature and with an electrical field of the electrical field strength. In the example, the lead-zirconate-titanate thin film 102 is at least intermittently treated simultaneously with the heat and the electrical field.

During treatment, in a step 206 it is checked whether a predetermined treatment time has elapsed or a resistance of the lead-zirconate-titanate thin film 102 measured during the treatment time reaches or exceeds a specified resistance value.

When it is determined that the treatment time has passed, or when the measured resistance of the lead-zirconate-titanate thin film 102 reaches or exceeds the specified resistance value, the method is ended. Otherwise, the treatment is continued in step 204.

That is, an end of regeneration is detected when the resistance reaches or exceeds a specified resistance value.

It may be provided that the temperature of the lead-zirconate-titanate thin film 102 is measured and a supplied heat is determined so that the measured temperature is the specified temperature.

In one embodiment of the method, the lead-zirconate-titanate thin film 102 is heated by means of the heater 104 near the lead-zirconate-titanate thin film 102.

In one embodiment, the lead-zirconate-titanate thin film 102 is heated by means of the heater 104 in the lead-zirconate-titanate thin film 102.

What is claimed is:

1. A method for regenerating a lead-zirconate-titanate thin film, comprising the following steps:
treating the lead-zirconate-titanate thin film with a specified temperature under 350° Celsius at least partially produced by a heater different from the lead-zirconate-titanate thin film, and with a simultaneous exposure of the lead-zirconate-titanate thin film to an electrical field of a specified electrical field strength.

2. The method according to claim 1, wherein the specified temperature is 220° Celsius or below 220° Celsius.

3. The method according to claim 1, wherein the lead-zirconate-titanate thin film is heated using the heater from outside the lead-zirconate-titanate thin film.

4. The method according to claim 1, wherein the lead-zirconate-titanate thin film is heated using the heater in the lead-zirconate-titanate thin film.

5. The method according to claim 1, wherein a resistance of the lead-zirconate-titanate thin film is determined, and wherein an end of the regeneration is detected when the resistance reaches or exceeds a specified resistance value.

6. An apparatus for regenerating a lead-zirconate-titanate thin film, the apparatus comprising:
a heater different from the lead-zirconate-titanate thin film, which is configured to treat the lead-zirconate-titanate thin film at a specified temperature below 350° Celsius; and
a device configured to generate an electrical field, wherein the device is configured to generate an electrical field having a specified electrical field strength, and to treat the lead-zirconate-titanate thin film using the electrical field.

7. The apparatus according to claim 6, further comprising:
a controller configured to control the heater and the device to simultaneously treat the lead-zirconate-titanate thin film for a specified treatment time.

8. The apparatus according to claim 6, wherein the specified temperature is 220° Celsius or below 220° Celsius.

9. The apparatus according to claim 6, wherein the apparatus is configured to heat the lead-zirconate-titanate thin film using the heater near the lead-zirconate-titanate thin film.

10. The apparatus according to claim 6, wherein the apparatus is configured to heat the lead-zirconate-titanate thin film using the heater in the lead-zirconate-titanate thin film.

11. The apparatus according to claim 6, wherein the apparatus is configured to determine a resistance of the lead-zirconate-titanate thin film and to detect an end of regeneration when the resistance reaches or exceeds a specified resistance value.
